(19) United States
(12) Patent Application Publication
(10) Pub. No.: US 2020/0109320 A1
(43) Pub. Date: Apr. 9, 2020

(54) LAMINATING FILM ADHESIVES WITH ULTRA-LOW MOISTURE PERMEABILITY

(71) Applicant: HENKEL IP & HOLDING GMBH, Duesseldorf (DE)

(72) Inventor: Hong JIANG, Irvine, CA (US)

(21) Appl. No.: 16/704,235

(22) Filed: Dec. 5, 2019

Related U.S. Application Data
(63) Continuation of application No. PCT/US2018/037457, filed on Jun. 14, 2018.
(60) Provisional application No. 62/519,483, filed on Jun. 14, 2017.

(51) Int. Cl. C09J 123/26; C08L 23/26; C08L 23/22; C09J 123/22; C09J 5/00; B32B 25/18; B32B 17/06; B32B 25/08; B32B 37/12; H01L 51/52; H01L 51/44

(52) U.S. Cl. CPC C09J 123/26; B32B 2255/20; C08L 23/22; C09J 123/22; C09J 5/00; B32B 25/18; B32B 17/063; B32B 25/08; B32B 37/12; H01L 51/5253; H01L 51/448; C08L 2203/206; C08L 2205/025; C09J 2203/326; C09J 2409/00; B32B 2255/10; C08L 23/26

(57) ABSTRACT

The present invention relates to curable barrier encapsulants or sealants for electronic devices that have pressure sensitive adhesive properties. The encapsulants are especially suitable for electronic devices that require low water vapor transmission rate.

### FIELD OF THE INVENTION

The present invention relates to a barrier pressure sensitive film adhesives with excellent moisture barrier properties. The barrier pressure sensitive film adhesives are particularly suitable as pressure-sensitive adhesives for encapsulating moisture-sensitive electronic devices, such as OLED and OPV. The barrier pressure sensitive film adhesive is also suitable for roll-to-roll possess applications for faster through-put.

### BACKGROUND OF THE INVENTION

Electronic devices and circuits, such as, organic photovoltaics (OPV), organic light emitting diodes (OLED), organic electrophoretic displays, organic electrochromic displays, and the like, are widely prevalent. OLED, for example, have utility in virtual-view and direct-view displays, as lap-top computers, televisions, digital watches, telephones, pagers, cellular telephones, calculators, large-area devices.

Various package geometries are known for organic electronic devices and circuits, and in general, these geometries consist of an active organic component disposed between a substrate/backsheet (hereinafter interchangeably used) and a cover/frontsheet/barrier films (hereinafter interchangeably used), and the substrate and cover are adhered together with a laminating adhesive/barrier pressure sensitive film adhesive/encapsulant (hereinafter interchangeably used) that encloses the active organic component. One or both of the substrate and the cover are made of a transparent material, for example, transparent glass and flexible thin plastic barrier films. The active organic component is attached to the substrate, and in some embodiments, is covered with an inorganic barrier coating, a buffer film or a coating composed of an inorganic and/or organic layer that seals the contact area between the component and the substrate at its perimeter. An encapsulant is applied over the active organic component, and over the barrier coating, when present. This encapsulant fills the space between the substrate and the cover, encloses the active organic component and adheres the substrate to the cover. In some embodiments, a desiccant package, in the form of a pouch, or a thin or thick film, is attached to the cover, usually in an indentation or cavity in the cover, or alternatively, the desiccant is provided in grooves within the cover.

Many active organic components within organic electronic devices are susceptible to degradation by moisture and oxygen. For example, an OLED, simply described, consists of an anode, a light emitting layer, and a cathode. A layer of a low work function metal is typically utilized as the cathode to ensure efficient electron injection and low operating voltages. Low work function metals are chemically reactive with oxygen and moisture, and such reactions will limit the lifetime of the devices. Oxygen and moisture will also react with the light emitting organic materials and inhibit light emission. Therefore, the packages surrounding the active organic components should be designed to restrict transmission of both oxygen and water vapor from the environment to the active organic components.

An encapsulant with pressure sensitive adhesive properties can be used to restrict transmission of water vapors, and the pressure sensitive film adhesive is typically provided in a thin film between two silicone release carrier liners as an encapsulant film. Upon removal of one of the liners, the exposed encapsulant film is attached to either the cover or the substrate of the device. Subsequently, the second liner is removed, allowing the cover and the substrate to be laminated (or attached) to one another. The encapsulant film must maintain adhesion and flexibility upon long term exposure to strain.

An encapsulant film or encapsulant (hereinafter interchangeably used) with pressure sensitive adhesive properties can facilitate manufacturing through-put of the device. While manufacturing speed and toxicity are improved for encapsulant with pressure sensitive adhesive properties, drawbacks include poor wet out and void formation during assembly because films typically have higher viscosity than their liquid encapsulant counterparts at assembly temperatures. This problem is exacerbated for substrate that contains components such as, electrodes, bus bars, ink steps, integrated circuits, wires, and the like, due to their irregular surfaces. In order to obtain better wet out and to minimize the formation of voids, hot lamination is usually applied to the uncured encapsulant film. However, organic components are sensitive to heat and prolonged exposure to heat is detrimental to the components.

WO 2009/148722 and WO 2011/062932 disclose the use of 300,000 Da weight average molecular weight (Mw) polyisobutylene-based encapsulants. Such encapsulants yield pressure sensitive adhesive films having high viscosity, and thus are susceptible to voids or air bubbles in organic electronic devices. While application temperature can be increased to minimize this problem, active organic components start to decompose at about 120° C.

WO2007/087281 requires about 20 to 90 wt % of a tackifier to about 10 to 80 wt % of polyisobutylene resin. Also, the weight average molecular weight (Mw) of the polyisobutylene resin is about 300,000 g/mol, 500,000 or more. Due to this high Mw, large quantities of the tackifier is required to achieve any adhesion to the substrates, which leads to haze and water absorption.

U.S. Pat. No. 8,232,350 requires a multifunctional (meth)acrylate monomer without any tackifier. The multifunctional (meth)acrylate monomers provide crosslinkable functionalities; however, this can lead to rigid films and low tack to substrates.

WO 2013/165637 is directed to polyisobutylene having a Mw of about 1,000 to about 95,000 and a functionalized polyisobutylene, however; this can lead to lower optical percent transmission for optical devices.

There is a need in the art for a curable encapsulant film that can laminate at temperatures below 120° C., form a void-free encapsulant on irregular surfaces, and maintain good adhesion with low water vapor transmission rate with high percent transmission.

### SUMMARY OF THE INVENTION

The invention provides curable encapsulants suitable for sealing moisture-sensitive electronic devices. The curable encapsulants have ultra-low moisture permeability, which extend the longevity of the device.

In one embodiment, the curable encapsulants is pressure-sensitive film adhesive comprising a (A) polyisobutylene, (B) a (meth)acrylate-functionalized polyisobutylene, (C) less than about 10 wt % of a tackifier, and (D) a free radical initiator. The ratio of the polyisobutylene to the (meth)acrylate-functionalized polyisobutylene ranges from about 1:0.2 to about 1:5. Also, the composition is free of added (meth)acrylic monomer with Mw less than about 1,000 Da. The curable encapsulants may further comprise a diluent, wax, antioxidant, and/or desiccant fillers.

In another embodiment, the curable encapsulant is a composition comprising (a) a polyisobutylene having a Mw of greater than 100,000 Da; (b) a (meth)acrylate-functionalized polyisobutylene having (i) a Mw of from about 1,000 to about 95,000 Da and (ii) greater than one (meth)acrylate functional group per polyisobutylene; and (c) a free radical initiator. The composition is essentially free of a (meth)acrylic monomer with Mw less than about 1,000 Da.

Another embodiment is directed to a method of forming encapsulant comprising the steps of: (1) mixing (A) polyisobutylene, (B) a (meth)acrylate-functionalized polyisobutylene, (C) less than about 10 wt % of a tackifier, and (D) a free radical initiator with a (E) diluent to form a mixture; (2) coating or casting the mixture to a thickness of about 0.001 to about 100 mm on a first liner film; and (3) evaporating or driving off the diluent to form a b-staged film; and (4) curing the b-staged film with UV-vis to form a cured film. A second liner may be placed on either the b-staged film or the cured film for storage and transport.

In another embodiment, a bundled barrier film is formed by (1) mixing (A) polyisobutylene, (B) a (meth)acrylate-functionalized polyisobutylene, (C) less than about 10 wt % of a tackifier, and (D) a free radical initiator with a (E) diluent to form a mixture; (2) coating or casting the mixture to a thickness of about 0.001 to about 100 mm on a barrier film; and (3) evaporating or driving off the diluent to form a b-staged film; and (4) curing the b-staged film with UV-vis to form a cured film on the barrier film. A second liner may be placed on either the b-staged film or the cured film for storage and transport. For this bundle process, the pressure sensitive adhesive film is laminated directly onto the barrier film as a cover liner.

Yet another embodiment is directed to a method of a device: (i) preparing an encapsulant, wherein the encapsulant is a cured pressure sensitive film adhesive comprising (A) polyisobutylene, (B) a (meth)acrylate-functionalized polyisobutylene, (C) less than about 10 wt % of a tackifier, and (D) a free radical initiator, wherein the encapsulant has a first side and a second side; (ii) applying the first side of the encapsulant onto a first substrate; and (iii) applying a second substrate onto the second side of the encapsulant. The encapsulant adheres the first substrate and the second substrate together as a barrier pressure sensitive adhesive. The barrier pressure sensitive adhesive protects actives such as OLED, OPV, CIGS or Quantum dots from moisture ingress to prolong longevity of the device. Also, the substrates, independently, are PI, barrier film/PET, barrier film/COP, thin film encapsulation layer.

Yet another embodiment is directed to devices comprising the above described cured encapsulants. Devices include electronic, optoelectronic, OLED, photovoltaic cells, organic photovoltaic cells, flexible thin film organic photovoltaic cells, CIGS photovoltaic cells, and the like.

Another embodiment is directed to a film laminate comprising the above described cured encapsulant coated on the cover liner that comprises SiN, SiO2 or Al2O3.

### BRIEF DESCRIPTION OF THE DRAWINGS

FIG. 1 is a cross section of a device, where a barrier encapsulant is adhered to a substrate and a barrier film, and protects an active encapsulated in the two layers.

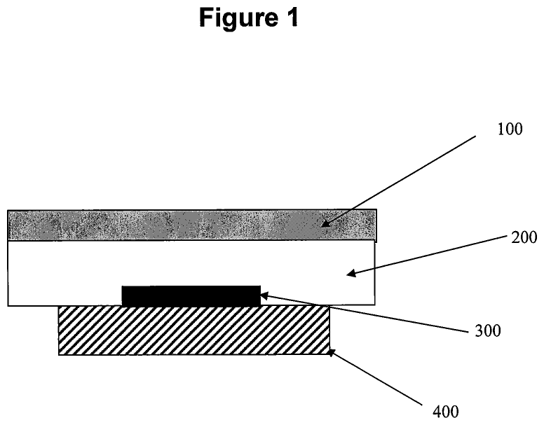

### DETAILED DESCRIPTION OF THE INVENTION

All references cited herein are incorporated in their entirety by reference.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing of the present disclosure. All publications, patent applications, patents and other references mentioned herein are incorporated by reference in their entirety. The materials, methods, and examples disclosed herein are illustrative only and not intended to be limiting.

As used in the specification and in the claims, the term “comprising” may include the embodiments “consisting of and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of and “consisting essentially of the enumerated ingredients/steps, which allows the presence of only the named ingredients/steps, along with any impurities that might result therefrom, and excludes other ingredients/steps.

Numerical values in the specification and claims of this application, particularly as they relate to polymers or polymer compositions, reflect average values for a composition that may contain individual polymers of different characteristics. Furthermore, unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently combinable (for example, the range of “from 2 to 10” is inclusive of the endpoints, 2 and 10, and all the intermediate values). The endpoints of the ranges and any values disclosed herein are not limited to the precise range or value; they are sufficiently imprecise to include values approximating these ranges and/or values. As used herein, approximating language may be applied to modify any quantitative representation that may vary without resulting in a change in the basic function to which it is related. Accordingly, a value modified by a term or terms, such as “about,” may not be limited to the precise value specified, in some cases. In at least some instances, the approximating language may correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11”, and “about 1” may mean from 0.9-1.1. Other meanings of “about” may be apparent from the context, such as rounding off, so, for example “about 1” may also mean from 0.5 to 1.4.

As used in herein, the term, “essentially free” means that the compositions may not include more than trace amounts of the named component.

As used in herein, the term, “no additional added component” means that the named component is purposed not added, while trace amounts may be present.

As used herein, the term, “curable barrier pressure sensitive adhesive” is a mixture with solvent, that is ready to be formed into a film, upon removal of the solvent. The “curable barrier pressure sensitive film adhesive” is an encapsulant without solvent in a b-stage film state, ready to be cured.

The term, “radiation cure” herein refers to toughening, hardening or vulcanization of the curable portion of the encapsulant through actinic radiation exposure. Actinic radiation is electromagnetic radiation that induces a chemical change in a material, including electron-beam curing, ultraviolet (UV) and visible light curing. The initiation of this cure is achieved through the addition of an appropriate photoinitiator. The cure of the encapsulant is achieved by direct exposure to ultraviolet (UV) or visible light or by indirect exposure through transparent lid or cover sheet that are made of polyester, polycarbonate, glass, and the like.

In one embodiment, the curable barrier pressure sensitive adhesive comprises a (A) polyisobutylene, (B) a (meth)acrylate-functionalized polyisobutylene, (C) less than about 10 wt % of a tackifier, and (D) a free radical initiator.

In another embodiment, the curable barrier pressure sensitive adhesive comprises (a) a polyisobutylene having a Mw of greater than 100,000 Da; (b) a (meth)acrylate-functionalized polyisobutylene having (i) a Mw of from about 1,000 to about 95,000 Da and (ii) greater than one (meth)acrylate functional group per polyisobutylene; and (c) a free radical initiator. The upper limit for this PIB is less than about 1,000,000 Da.

Polyisobutylene (PIB) is substantially a homopolymer of isobutylenes. It can also be called polybutene and butyl rubbers. It usually contains less than 75% terminal alpha olefins per polymer chain. The PIB is free of any other radical reactive functional groups including, but are not limited to, acrylate, (meth)acrylate, styrenic C=C bonds, diallyl, maleic anhydride, and the like. Commercially available PIB includes, but not limit to, Oppanol, Glissopal, and Indopol. While many of these PIBs may contain even up to 75% terminal alpha C=C bonds, the reactivity of these PIBs towards free radical reaction are relatively low and incomplete, and are therefore considered to be non-reactive or non-curable PIBs. In one embodiment, the weight average molecular weight (Mw) of the PIB is greater than about 100,000. In another embodiment, the Mw of the PIB is less than about 100,000. Yet in another embodiment, the PIB is a mixture of PIBs having a Mw of greater than about 100,000 and less than about 100,000.

The total content of the PIB ranges from about 10 to about 90 weight percent, more preferably from about 20 to about 60 weight percent, based on the total weight of the curable encapsulant, without accounting for any solvents.

PIB diluents may further be added to the encapsulant. PIB diluents typically have a Mw ranging from about 1,000 to about 10,000 Da. These have a low viscosity and can decrease the overall viscosity of the encapsulant to achieve 100% wet out upon heating.

(Meth)acrylate-functionalized polyisobutylene is a polyisobutylene with terminal or pendant (meth)acrylate functional groups. Examples of terminal and/or grafted pendant functionalities that are reactive and curable by radiation includes, but are not limited to, those selected from the groups consisting of acrylate, methacrylate, vinyl, vinyl ether, propenyl, crotyl, allyl, silicon-hydride, vinylsilyl, propargyl, cycloalkenyl, thiol, glycidyl, aliphatic epoxy, cycloaliphatic epoxy, oxetane, itaconate, maleimide, maleate, fumarate, cinnamate esters, styrenic, acrylamide, methacrylamide, and chalcone groups.

Exemplary (meth)acrylate-functionalized polyisobutylene includes, but are not limited to, diallyl polyisobutylene, di(meth)acrylate polyisobutylene, and vinyl-terminal polyisobutylene. Representative polyisobutylene (meth)acrylate are described in U.S. Pat. No. 5,171,760 issued to Edison Polymer Innovation Corp., U.S. Pat. No. 5,665,823 issued to Dow Corning Corp., and Polymer Bulletin, Vol. 6, pp. 135-141 (1981), T. P. Liao and J. P. Kennedy. Representative polyisobutylene vinyl ethers are described in Polymer Bulletin, Vol. 25, pp. 633 (1991), J. P. Kennedy, and in U.S. Pat. Nos. 6,054,549, 6,706,77962 issued to Dow Corning Corp. Preferred functionalized PIB is a free radical reactive polyisobutylene, butyl rubber derivatives, and like, which are terminated or grafted with (meth)acrylic or 75% of alpha-olefin functional groups. Particularly, the functionalized polyisobutylene has (i) a Mw of from about 1,000 to about 95,000 Da and (ii) contains greater than one free-radical reactive functional group per polymer chain. The functionalized PIB is formed with free-radical functional group selected from terminal (meth)acrylates, pendant (meth)acrylates, terminal acrylates, and/or pendant acrylates.

(Meth)acrylate-functionalized polyisobutylene in the curable encapsulant is in the amount ranging from about 5 to about 90 weight percent, more preferably from about 10-50 weight percent, based on the total weight of the curable encapsulant, without accounting for any solvent.

The ratio of the PIB to (meth)acrylate-functionalized polyisobutylene ranges from about 1:0.2 to about 1:5 in the composition. In a more preferred embodiment, the ratio of the PIB to (meth)acrylate-functionalized polyisobutylene ranges from about 1:0.5 to about 1:4 in the composition.

Suitable tackifiers include, but are not limited to, any resins or mixtures compatible (or miscible) to PIB and such as (1) natural or modified rosins such, for example, as gum rosin, wood rosin, tall oil rosin, distilled rosin, hydrogenated rosin, dimerized rosin, and polymerized rosin; (2) glycerol and pentaerythritol esters of natural or modified rosins, such, for example as the glycerol ester of pale, wood rosin, the glycerol ester of hydrogenated rosin, the glycerol ester of polymerized rosin, the pentaerythritol ester of hydrogenated rosin, and the phenolic-modified pentaerythritol ester of rosin; (3) copolymers and terpolymers of natural terpenes, e.g., styrene/terpene and D-methyl styrene/terpene; (4) polyterpene resins having a softening point, as determined by ASTM method E28,58T, of from about 80 to about 150° C.; the latter polyterpene resins generally resulting from the polymerization of terpene hydrocarbons, such as the bicyclic monoterpene known as pinene, in the presence of Friedel-Crafts catalysts at moderately low temperatures; also included are the hydrogenated polyterpene resins; (5) phenolic modified terpene resins and hydrogenated derivatives thereof, for example, as the resin product resulting from the condensation, in an acidic medium, of a bicyclic terpene and phenol; (6) aliphatic petroleum hydrocarbon resins having a Ball and Ring softening point of from about 70 to about 135° C.; the latter resins resulting from the polymerization of monomers consisting of primarily of olefins and diolefins; also included are the hydrogenated aliphatic petroleum hydrocarbon resins; (7) alicyclic petroleum hydrocarbon resins and the hydrogenated derivatives thereof; and (8) aliphatic/aromatic or cycloaliphatic/aromatic copolymers and their hydrogenated derivatives. The desirability and selection of the particular tackifiers can depend upon the compatibility with other components in the encapsulant film formulations. Also, the color and hydrophobicity of the tackifier should be considered when choosing the tackifier for the encapsulant.

Tackifier may also be a liquid tackifier, having a Ring and Ball softening point below about 25° C.) are liquid tackifying diluents that include polyterpenes such as Wingtack 10 available from Sartomer, and Escorez 2520 available from ExxonMobil Chemical. The synthetic liquid oligomers are high viscosity oligomers of polybutene, polypropene, polyterpene, and etc., which are permanently in the form of a fluid. Examples include polyisoprene, available as LIR 50 from Kuraray, and Amoco's polybutenes available under the name Indopol, Wingtack 10 from Sartomer and synthetic liquid oligomer polybutenes such as Indopol 300 from Amoco.

When present, the encapsulant compositions of the invention will typically comprise the tackifier in amounts of less than about 20, 19, 18, 17, 16, 15, 14, 13, 12, 11, 10, 9, 8, 7, 6, 5, 4, 3, wt %, from about 0.1 to about 5 wt % based on the total weight of the encapsulant, not accounting for any solvent.

Preferred tackifiers include rosin esters derived from wood rosin, gum rosin or tall oil rosin and terpene resins. Also preferred are aliphatic/aromatic or cycloaliphatic/aromatic copolymers and their hydrogenated derivatives. These tackifiers impart excellent and aggressive adhesion and miscibility with PIBs and (meth)acrylate-functionalized polyisobutylene.

Particularly preferred tackifiers have a low degree of Gardner's color, or are colorless to provide high percent transmission.

The radical cure initiator includes a radical polymerization initiator that generates radicals by being decomposed by electromagnetic energy rays such as UV rays, or a thermally decomposable radical initiator that generates radicals by being thermally decomposed. Radical photopolymerization initiating system comprising one or more photoinitiators can be found in Fouassier, J-P., Photoinitiation, Photopolymerization and Photocuring Fundamentals and Applications 1995, Hanser/Gardner Publications, Inc., New York, N.Y.

The radical photopolymerization initiators include Type I alpha cleavage initiators such as acetophenone derivatives such as 2-hydroxy-2-methylpropiophenone and 1-hydroxycyclohexyl phenyl ketone; acylphosphine oxide derivatives such as bis(2,4,6-trimethylbenzoyl) phenylphosphine oxide; and benzoin ether derivatives such as benzoin methyl ether and benzoin ethyl ether. Commercially available radical photoinitiators include Irgacure 651, Irgacure 184, Irgacure 907, Darocur 1173 and Irgacure 819 from Ciba Speciality Chemical. Type II photointiators are also suitable for the curable encapsulant, and they include benzophenone, isopropylthioxanthone, and anthroquinone. Many substituted derivatives of the aforementioned compounds may also be used. The selection of a photoinitiator for the radiation curable encapsulant is familiar to those skilled in the art of radiation curing. The photoinitiator system will comprise one or more photoinitiators and optionally one or more photosensitizers. The selection of an appropriate photoinitiator is highly dependent on the specific application in which the encapsulant is to be used. A suitable photoinitiator is one that exhibits a light absorption spectrum that is distinct from that of the resins, and other additives in the encapsulant. The amount of the photoinitiator is typically is in a range of about 0.01 to about 10 wt %, preferably, from about 0.01 to about 5 wt %, based on the total weight of the encapsulant, without accounting for solvent.

In one embodiment, an organic photovoltaic cell with an encapsulant layer containing no volatile low molecular weight (having a Mw less than about 1,000 Da) organic molecules. Without wishing to be bound by theory, it is believed that presence of such molecules in the encapsulant layers may create voids upon heating, affect the adhesion between the encapsulant layer and the active organic layer, and more importantly, change the morphology of active organic layers because of the migration and solvation of low organic molecules in the active organic layer. As it is known from “Organic Photovoltaics: Challenges and Opportunities,” by Russell Gaudiana, J. of Polymer Science: Part B: Polymer Physics 2012, DOI: 10.1002/polb.23083), the morphology of active layer is crucial to the module efficiency. For example, a high percentage of process time is focused on controlling the rate of evaporation of the solvent from active organic components because it is the major factor in establishing the optimum morphology of the active layer. The coating quality of the active layer is determined by the precise thickness, surface roughness, and pinhole-free film as possible.

The curable barrier pressure sensitive adhesive may further comprise plasticizers, wax, and mineral oil to adjust the viscosity of the formulations.

A non-limiting example of a plasticizer includes polar plasticizer, solid plasticizer, liquid plasticizer (natural and synthetic), and plasticizer that is primarily aliphatic in character and is compatible with PIB. Solid plasticizer is a solid at ambient temperature, and preferably has a softening point above 60° C. Any solid plasticizer that can subsequently recrystallize in the encapsulant is suitable. Examples include 1,4-cyclohexane dimethanol dibenzoate, Benzoflex 352, available from Genovique Specialties. A non-limiting example of a natural liquid plasticizer is a vegetable oil. Synthetic liquid plasticizers include liquid polyolefins, iso-paraffins or paraffins of moderate to high molecular weight. Examples include SpectraSyn Plus 6 from ExxonMobil Chemical.

Suitable waxes compatible to PIB include petroleum based, conventional wax, natural-based wax, functionalized wax, and polyolefin copolymers. The term petroleum derived wax, includes both paraffin and microcrystalline waxes having melting points within the range of from about 130° F. to about 225° F. as well as synthetic waxes such as low molecular weight polyethylene or Fisher-Tropsch waxes. Most preferred are polyethylene or Fisher-Tropsch waxes with a melting point of at least about 175° F. Amounts of wax necessary to achieve the desired properties will typically range from about 0.5 to about 10 wt %, based on the total weight of the encapsulant, not accounting for solvent.

A non-limiting example of oils include paraffinic and naphthenic petroleum oil, highly refined technical grade white petroleum mineral oils such as Kaydol oil from Crompton-Witco and naphthenic petroleum oil such as Calsol 5550 from Calumet Lubricants. Diluent can also be a liquid tackifier (having a Ring and Ball softening point below about 25° C.), synthetic liquid oligomer, and mixtures thereof. When present, the formulations of the invention will typically comprise the oil diluent in amounts of less than about 50 wt % based on the total weight of the encapsulant, not accounting for solvent.

The curable barrier pressure sensitive adhesive may optionally comprise additives including thermal stabilizers, antioxidants, UV absorbers, and hindered amine light stabilizers. Any known thermal stabilizer may be suitable, and preferred general classes of thermal stabilizers include, but are not limited to, phenolic antioxidants, alkylated monophenols, alkylthiomethylphenols, hydroquinones, alkylated hydroquinones, tocopherols, hydroxylated thiodiphenyl ethers, alkylidenebisphenols, O-, N- and S-benzyl compounds, hydroxybenzylated malonates, aromatic hydroxybenzyl compounds, triazine compounds, aminic antioxidants, aryl amines, diaryl amines, polyaryl amines, acylaminophenols, oxamides, metal deactivators, phosphites, phosphonites, benzylphosphonates, ascorbic acid (vitamin C), hydroxylamines, nitrones, thiosynergists, benzofuranones, indolinones, and the like, and mixtures thereof. Use of a thermal stabilizer is optional and in some instances, is not preferred, especially if it reacts and degrades the active organic component within the electronic device. When thermal stabilizers are used, they may be present at a level of about 0.00005 wt % and up to about 10 wt % based on the total weight of the encapsulant, not accounting for solvent.

Any known UV absorber may be suitable for use in the encapsulant composition, and preferred general classes of UV absorbers include, but are not limited to, benzotriazole derivatives, hydroxybenzophenones, hydroxyphenyl triazines, esters of substituted and unsubstituted benzoic acids, and the like and mixtures thereof. Hindered amine light stabilizers (HALS) can be used and are also well known in the art. Generally, hindered amine light stabilizers are secondary, tertiary, acetylated, N-hydrocarbyloxy substituted, hydroxyl-substituted N-hydrocarbyloxy substituted, or other substituted cyclic amines which are characterized by a substantial amount of steric hindrance, generally derived from aliphatic substitution on the carbon atoms adjacent to the amine function. Use of a UV absorber is optional and in some instances, is not preferred, especially if it reacts and degrades active organic component within the electronic device. When UV absorbers are utilized, they may be present in the formulation at a level of about 0.00005 wt % and up to about 10 wt % based on the total weight of the curable encapsulant, not accounting for solvent.

Examples of silane coupling agents that are useful in the encapsulant composition include, but are not limited to, C3-C24 alkyl trialkoxysilane, (meth)acryloxypropyltrialkoxysilane, chloropropylmethoxysilane, vinylthmethoxysilane, vinylthethoxysilane, vinyltrismethoxyethoxysilane, vinylbenzylpropylthmethoxysilane, aminopropyltrimethoxysilane, vinylthacetoxysilane, glycidoxypropyltrialkoxysilane, beta.-(3,4-epoxycyclohexyl) ethyltrimethoxysilane, mercaptopropylmethoxysilane, aminopropyltrialkoxysilane, and mixtures of two or more thereof. Use of a silane coupling agents is optional and in some instances, is not preferred, especially if it reacts and degrades active organic component within the electronic device. When silane coupling agents are utilized, they may be present in the formulation at a level of about 0.01 wt % and up to about 10 wt % based on the total weight of the curable encapsulant, not accounting for solvent.

Other additives conventionally used in pressure sensitive adhesives to satisfy different properties and meet specific application requirements also may be added to the curable encapsulant. Such additives include, but are not limited to, pigments, flow modifiers, dyestuffs, which may be incorporated in minor or larger amounts into the encapsulant composition, depending on the purpose.

In a preferred embodiment, the components are dissolved in a solvent to form a mixture. Typical solvents are aprotic organic solvents; hence they cannot take part in the reaction. Such solvents can be, but are not limited to, cyclic, linear and/or branched ethers, hydrocarbons such as alkanes or alkenes, ketones, aromatic solvents such as pyridine, toluene and/or naphthalene, halogenated solvents such as methylenechloride as well as others. It is also possible to use two or more different solvents, or a mixture of one or more different solvents. It is then often an advantage, that the used solvents are at least partly miscible in the chosen concentration ranges. It is important to note that it is not a requirement that the components are fully soluble in the solvent. Often a limited solubility is sufficient, hence the remainder of the components material is typically dispersed in the reaction media. This can be a favoured reaction conditions when the components are in solid form, since it is not required to fully dissolved. Typically, the encapsulant components are all dissolved in a solvent or a mixture of solvents e.g., xylene, toluene, heptane, hexane, cyclohexane, and the like.

In a further embodiment, desiccant may be used to improve the moisture barrier properties of the encapsulant. When added, desiccant comprise up to 20 wt % of the encapsulant, not including the solvent. The fillers with desiccant properties (referred to as desiccant fillers) suitable for use may be any of those that provide an appropriate moisture scavenging rate, capacity, and residual moisture level (the lowest level of moisture at which the desiccant can actively scavenge water) to meet the allowable moisture level for the specific electronic device. The desiccant fillers will be capable of reacting with, absorbing, or adsorbing water and/or water vapor. A representative list of such desiccants can be found in Dean, J. Lange's Handbook of Chemistry, 1999, McGraw Hill, Inc., New York, N.Y., pp. 11.5.

In general, suitable desiccants include metal oxides, such as, CaO, BaO, MgO; other oxides, such as SiO₂, P₂O₅, Al₂₃; metal hydrides, such as CaH₂, NaH, LiAl₄; metal salts, such as CaSO₄, Na₂SO₄, MgSO₄, CaCO₃, K₂CO₃, and CaCl₂; powdered zeolites, such as 4A and 3A molecular sieves; metal perchlorates, such as, Ba(ClO₄)₂, Mg(CIO₄)₂; superabsorbent polymers, such as, lightly cross linked poly(acrylic acid); and metals that react with water, such as calcium. As with any filler, the desiccant filler particle size, particle size distribution, shape, and surface functionality will affect the level to which it can be loaded into a resin system and what rheology may result. Such factors are understood by those skilled in the art and are not otherwise relevant to the current inventive compositions. Blends of the more common non-desiccant fillers disclosed above and these desiccant fillers are contemplated and described within the examples. A common range for the particle size of the desiccant filler is from about 0.001 to about 200 micrometers. The practitioner with skill in the art will be able to determine the appropriate particle size range for the resin, rheology, and scavenging rate needed for the particular end use application.

To form a b-staged, curable barrier pressure sensitive film adhesive, the components of the curable barrier pressure sensitive adhesive are mixed with a solvent, and then coated onto a liner. For example, the sheets may be formed by solution casting or dip coating. Solution casting is prepared using techniques known in the art. The solution is cast as a film with a specified weight per square meter, and the solvent is then evaporated to form the solid encapsulant film. The solvent can be removed by heat and/or air. The film thickness ranges from about 0.001 mm to about 10 mm, preferably from about 0.005 to about 0.5 mm. The dried film on the liner is a b-staged, curable barrier pressure sensitive film adhesive.

UV-vis radiation, ranging from about 280 to about 450 nm, is applied onto the b-staged film to form a cured barrier pressure sensitive film adhesive.

Another liner is applied onto the cured film to minimize contamination, sandwiching the cured barrier film in between the two liners. The linear are typically coated with silicone for easy removal. The encapsulant films can be delivered as sheets or in rolls on release liners such as PET, glass, etc.; or between carrier films, such as silicone PET or Kraft paper release liners. The sheets or rolls comprising the encapsulant films may be produced by any suitable process.

The encapsulant films can then be stored or transported at this state. The encapsulant film is substantially clear and substantially transparent, having a Haze value less than about 2, less than about 1.5, and even less than about 1. The encapsulant film also has water vapor transmission rate (WVTR) value of less than about 0.3, measured in accordance with ASTM F-1249, 38° C. and 100% relative humidity.

The cured encapsulant films may be used in a roll-to-roll lamination process for faster throughput in making OLED devices.

Upon removal of the first liner, the exposed cured barrier pressure sensitive adhesive film (200) is laminated to the barrier film (100) with pressure. Subsequently, the second liner of the cured barrier pressure sensitive adhesive film (200) is removed and laminated onto the substrate (400). The substrate (400) has an active (300). The active ranges from OLED, OPV, photovoltaic cells. In another embodiment, the cured barrier pressure sensitive adhesive film (200) is laminated to both barrier film (100) and substrate (400) simultaneously. Optionally, heat and/or vacuum can be applied to encourage lamination, and to remove any entrapped air and to eliminate any voids in between the layers.

In one embodiment, the substrate has irregular surfaces with peaks and voids, including electrical wirings, such as cross ribbons and bus bars. Therefore, the cured encapsulant must flow over and fill the voids of the substrate in a uniform manner. The photovoltaic cell may further comprise other functional film, sheet layers, encapsulant layers (e.g., dielectric layers or barrier layers) embedded within the module.

In one embodiment, the encapsulant film has irregular surfaces on both sides of the substrate and cover to facilitate deaeration during the lamination process. Irregular surfaces can be created by mechanically embossing or by melt fracture during extrusion of the sheets followed by quenching so that surface roughness is retained during handling. The surface pattern can be applied to the sheet through well-known, common art processes. For example, the extruded sheet may be passed over a specially prepared surface of a die roll positioned in close proximity to the exit of the extruder die. This imparts the desired surface characteristics to one side of the molten polymer exiting the die. Thus, when the surface of such a die roll has minute peaks and valleys, it will impart a rough surface to the side of the polymer sheet that passes over the roll, and the rough surface will generally conform respectively to the valleys and peaks of the roll surface. Such die rolls are described in, e.g., U.S. Pat. No. 4,035,549 and U. S. Patent Publication No. 2003/0124296.

In another embodiment, the encapsulant films may be in a single layer or in multilayer form. The term “single layer” refers to sheets that are made of or that consist essentially of adhesive described herein. When in a multilayer form, the sheet comprises sublayers, and at least one of the sub-layers is made of or consists essentially of the adhesive in the invention, while the other sub-layer(s) may be made of or comprise any other suitable polymeric material(s).

In another embodiment, a bundled barrier film is formed by (1) mixing (A) polyisobutylene, (B) a (meth)acrylate-functionalized polyisobutylene, (C) less than about 10 wt % of a tackifier, and (D) a free radical initiator with a (E) diluent to form a mixture; (2) coating or casting the mixture to a thickness of about 0.001 to about 100 mm on a barrier film; and (3) evaporating or driving off the diluent to form a b-staged film; and (4) curing the b-staged film with UV-vis to form a cured film on the barrier film. A second liner may be placed on either the b-staged film or the cured film for storage and transport. For this bundle process, the pressure sensitive adhesive film is laminated directly onto the barrier film as a cover liner. The cover liner may be sputtered with SiN, SiO2 or Al2O3.

In one embodiment, the curable encapsulant film is suitable as an encapsulant for optoelectronic, OLED, photovoltaic cells, organic photovoltaic cells, flexible thin film organic photovoltaic cells, CIGS photovoltaic cells, and the like. In one preferred embodiment, the encapsulant is suitable as an encapsulant for organic photovoltaics (OPV), where the moisture and oxygen barrier requirements are most demanding. The cured encapsulant film has numerous advantages over conventional liquid encapsulants. The cured encapsulant film described herein allows the material to fully flow around and over the irregular surfaces of the photovoltaic cell assembly during laminating process and therefore minimize air bubbles, and cell breakage. Further, the cured encapsulant provides high moisture and oxygen barrier properties and the optical clarity of the encapsulant layer. The cured encapsulant film maintains good adhesion and flexibility, and prevents delamination failure of the flexible display or thin film photovoltaic when it is bent or held vertical in rigid displays or photovoltaic for an extended period.

The following examples are provided to describe the invention in further detail. These examples, which set forth a preferred mode presently contemplated for carrying out the invention, are intended to illustrate and not to limit the invention.

### EXAMPLES

Components to the Samples are as follows.

Oppanol PIB series are from BASF.

(Meth)acrylate-functionalized polyisobutylene is a PIB with a two terminal acrylate functionalities and has a Mw of about 14,000. This was synthesized according to the method described in T. P . Liao and J. P. Kennedy, Polymer Bulletin, Vol. 6, pp. 135-141 (1981).

CN308 is a reactive polybutadiene diacrylate from Sartomer.

Irgacure series and Lucirin TPO-L are photoinitiators from BASF.

KE-100 and Kristallex 3085 are tackifiers from Arakawa Chemical and Eastman Chemicals, respectively.

Silane Z6040 and Z6030 are Glycidoxypropyltrimethoxysilane and methacryloxypropyltrimethoxysilane, respectively from Dow Corning.

Heptane is a solvent from Sigma Aldrich.

Viscosity, water vapor transmission rate (WVTR), percent transmittance (% T) Haze, shear strength of the samples were measured as follows.

Viscosities of the uncured encapsulants in solvent were measured using a Brookfield Viscometer, CP 51 at 25° C. at 100 rpm.

WVTR was measured with Mocon Permeatran-W Model3/33 at 38° C./100% RH according to ASTM F-1249. Optimal WVTR for the composition is less than about 0.3 at 38° C./100% RH.

Percent transmittance was measured by Datacolor 650.

Haze was measured by Datacolor 650.

Peel Strength of the cured encapsulant films were measured according to ASTMD903 at 12IPM on glass. The shear strength testing was performed at 23° C. and 50% relative humidity.

### Example 1

The components of Samples 1-6 are listed in Table 1. Comparative Sample 1 was prepared by mixing the components at 130° C. in a Brabender, or with a Glas-Col, as known to those of skill in the art. Comparative Samples 2-6 and Examples 1-2 were dissolved in heptane solvent until homogeneous. Typically, the samples had a viscosity range of about 200 to about 1,000 cps at 100 rpm.

TABLE 1

| | C1 | C2 | C3 | C4 | C5 | C6 | Ex 1 | Ex 2 |
|---|---|---|---|---|---|---|---|---|
| Oppanol B13 | 69.3 | | | | | | | 66.6 |
| (Mw 60,000) | | | | | | | | |
| Oppanol B100 | | 49.9 | 34.4 | 48.14 | 23.67 | 23.67 | 23.5 | |
| (Mw | | | | | | | | |
| 1,000,000) | | | | | | | | |
| (meth)acrylate- | 29.7 | | | 48.14 | 72.62 | 72.62 | 72.1 | 30 |
| functionalized | | | | | | | | |
| polyisobutylene | | | | | | | | |
| (Mw 14,000) | | | | | | | | |
| CN308 | 1 | 45 | 62.06 | | | | | 0 |
| Lucirin TPO-L | | | | | | | | 0 |
| Irgacure 4265 | | 1.48 | 1.03 | 2.18 | 2.18 | 2.18 | 1.44 | 0.99 |
| KE-100 | | 2.14 | 1.48 | 0 | 0 | | | 1.43 |
| Kristallex 3085 | | | | | | 0 | 1.44 | |
| Silane Z6040 | | 1.48 | 1.03 | 1.54 | 1.53 | 0 | | 0.98 |
| Silane Z6030 | | | | | | 1.53 | 1.52 | |

The encapsulants of Samples were then coated as a film and cured. Comparative Sample 1 was a hot melt adhesive and this was cast as a film with heat and then cooled. The rest of the samples were cast, evaporated the solvent was evaporated to develop a film, and then cured with UV-A, from 0.1-2 J/cm².

WVTR, % T, and peel strength were measured on the cured encapsulant films. The properties are listed in Table 2.

TABLE 2

| | C1 | C2 | C3 | C4 | C5 | C6 | Ex 1 | Ex 2 |
|---|---|---|---|---|---|---|---|---|
| UV Cure condition | 1000 mJ/cm2 | | | | | | | |
| | 5-6 mil | | | | | | | |
| WVTR at | 0.12 | 0.49 | 0.56 | 0.20 | 0.14 | 0.18 | 0.12 | 0.11 |
| 38 C/100% RH, | | | | | | | | |
| (PPM) | | | | | | | | |
| % T, 400-110 nm | >91% | >97% | | >97% | >97% | >97% | >97% | >97% |
| Haze | | 0 | NA* | 2.7 | 3.5 | 1.7 | 0.7 | 0 |
| Peel Strength (g- | | 0 | 0 | 4.6 | 1.2 | 1.1 | 61.6 | 62.1 |
| f/mm) on glass | | | | | | | | |

NA* - Haze could not be measured due to low adhesion and could not be transferred to the instrument.

The hot melt film of Cl had the lowest % T value.

The high molecular weight PIBs and (meth)acrylate monomers without any tackifiers of samples C2 and C3 had no peel strength.

Again, high molecular weight PIBs and (meth)acrylate-functionalized polyisobutylene of C4, C5 and C6 also had low peel strength.

A combination of PIB, regardless of its Mw values or mixtures of PIBs with varying molecular weights, (meth)acrylate-functionalized polyisobutylene and less than 5wt % of tackifier leads films, Ex 1 and Ex, 2 had the highest peel strength values. Moreover, the haze values of the examples, C1 and C2, had at least an order of magnitude lower than comparative samples, C4, C5 and C6. Also, the water vapor transmission rate is acceptable for Ex 1 and Ex 2.

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

1. A composition comprising:
a) a polyisobutylene;
b) a (meth)acrylate-functionalized polyisobutylene;
c) less than about 10 wt % of a tackifier, based on the total weight of the composition; and
d) a free radical initiator;
wherein the ratio of the polyisobutylene to the (meth)acrylate-functionalized polyisobutylene ranges from about 1:0.2 to about 1:5; and
wherein the composition is free of added (meth)acrylic monomer with weight average molecular weight (Mw) less than about 1,000 Da.

2. The composition of claim 1, wherein the encapsulant has a WVTR value of less than about 0.3 according to ASTM F-1249, 38° C. and 100% relative humidity.

3. The composition of claim 1, wherein the polyisobutylene comprises a mixture of (i) polyisobutylene having a Mw greater than 100,000 Da and (ii) polyisobutylene having a Mw less than 100,000 Da.

4. The composition of claim 1, wherein the tackifier is present at less than 5 wt %.

5. The composition of claim 1, wherein the tackifier is substantially clear and substantially transparent.

6. The composition of claim 1, wherein the ratio of the polyisobutylene to the (meth)acrylate-functionalized polyisobutylene ranges from about 1:05 to 1:4.

7. The composition of claim 1, which is a curable pressure sensitive adhesive film.

8. A cured composition of the curable pressure sensitive adhesive film of claim 7.

9. An article comprising the cured composition of claim 8.

10. The article of claim 9, which is an electronic device selected OLED, organic photovoltaic module, CIGS photovoltaic module or Perovskite photovoltaic module.

11. A film laminate comprising:
(a) a first film of the composition of claim 1 and
(b) a cover liner comprising SiN, SiO2 or Al2O3
wherein the first film is coated on the cover liner.

12. A composition comprising:
a) a polyisobutylene having a weight average molecular weight (Mw) of greater than 100,000 Da;
b) a (meth)acrylate-functionalized polyisobutylene having (i) a Mw of from about 1,000 to about 95,000 Da and (ii) greater than one (meth)acrylate functional group per polyisobutylene; and
c) a free radical initiator;
wherein the composition is essentially free of a (meth)acrylic monomer with Mw less than about 1,000 Da.

13. The composition of claim 12, wherein the polyisobutylene has a Mw of less than about 1,000,000 Da.

14. The composition of claim 12, wherein the (meth)acrylate functional group is in pendant position of the (meth)acrylate-functionalized polyisobutylene.

15. The composition of claim 12, wherein the (meth)acrylate functional group is in terminal position of the (meth)acrylate-functionalized polyisobutylene.

16. The composition of claim 12, further comprising less than 10 wt % of a tackifier, based on the total weight of the composition.

17. The composition of claim 11, which is a curable encapsulant.

18. A method of forming an encapsulant comprising the steps of:
(1) mixing the components of claim 1 with a diluent to form a mixture;
(2) coating or casting the mixture to a thickness of about 0.001 to about 10 mm on a liner;
(3) evaporating or driving off the diluent to form a b-staged film; and
(4) curing the b-staged film.

19. A method of forming a device comprising the steps of:
(i) preparing the encapsulant of claim 18, having a first side and a second side
(ii) applying the first side of the film laminate onto a first substrate;
(iii) applying a second substrate onto the second side of the film laminate without the liner; and
whereby the encapsulant adheres the first substrate and the second substrate together; and
wherein the first substrate and the second substrate are, independently, glass, PET, COP (cyclic olefin polymer), and PI.
